(19) United States
(12) Patent Application Publication
(10) Pub. No.: US 2026/0063745 A1
(43) Pub. Date: Mar. 5, 2026

(54) SYSTEMS, APPARATUSES, AND METHODS FOR PERFORMING ARTERIAL-SPIN LABELING

(71) Applicant: Siemens Healthineers AG, Forchheim (DE)

(72) Inventor: Yulin Chang, Belmont, MA (US)

(21) Appl. No.: 19/233,152

(22) Filed: Jun. 10, 2025

Related U.S. Application Data
(60) Provisional application No. 63/688,909, filed on Aug. 30, 2024.

(51) Int. Cl. G01R 33/563; G01R 33/54

(52) U.S. Cl. CPC G01R 33/5635; G01R 33/543

(57) ABSTRACT

A system for performing arterial-spin labeling (“ASL”) includes at least one memory configured to store instructions and at least one processor configured to execute the instructions to cause the system to perform a labelling phase and a control phase. The labelling phase includes a first plurality of radio frequency (“RF”) pulses and each RF pulse of the first plurality of RF pulses has a frequency offset and a phase offset. The control phase includes a second plurality of RF pulses and each RF pulse of the second plurality of RF pulses has the frequency offset and the phase offset and alternating RF pulses of the second plurality of RF pulses has an additional phase shift.

### CROSS-REFERENCE TO RELATED APPLICATION(S)

This application claims priority under 35 U.S.C. § 119 (e) to provisional U.S. patent application No. 63/688,909, filed Aug. 30, 2024, the entire contents of which are incorporated herein by reference.

### TECHNICAL FIELD

The present disclosure relates to systems, apparatuses, and/or methods for performing arterial-spin labeling (“ASL”).

### BACKGROUND

Arterial-spin labeling (“ASL”) is a non-invasive magnetic resonance (“MR”) technique used to measure blood perfusion by magnetically labeling water nuclei in blood before blood perfuses into tissue. ASL includes pulsed ASL (“PASL”) where blood surrounding an imaging volume is labeled and continuous ASL (“CASL”) or pseudo-continuous ASL (“pCASL”) where blood up-stream of an imaging volume is labeled using flow-driven adiabatic passage.

### SUMMARY

At least one example embodiment relates to a system for performing arterial-spin labeling (“ASL”). The system may include at least one memory configured to store instructions and at least one processor configured to execute the instructions to cause the system to perform a labelling phase and a control phase. The labelling phase may include a first plurality of radio frequency (“RF”) pulses, each RF pulse of the first plurality of RF pulses may have a frequency offset and a phase offset. The control phase may include a second plurality of RF pulses, each RF pulse of the second plurality of RF pulses may have the frequency offset and the phase offset and alternating RF pulses of the second plurality of RF pulses may have an additional phase shift.

In at least one example embodiment, the frequency offset may be based on deviations in a B₀ field in a labelling plane. In at least one example embodiment, the frequency offset may be based on a gyromagnetic ratio and the deviations in the B₀ field in the labelling plane.

In at least one example embodiment, the phase offset may be based on the frequency offset and a time between adjacent RF pulses of at least one of the first plurality of RF pulses or the second plurality of RF pulses. In at least one example embodiment, the frequency offset may be based on deviations in a B₀ field in a labelling plane. In at least one example embodiment, the frequency offset may be based on a gyromagnetic ratio and the deviations in the B₀ field in the labelling plane.

In at least one example embodiment, the labelling phase may be a pseudo-continuous ASL labelling phase.

In at least one example embodiment, the control phase may be a pseudo-continuous ASL control phase.

Also described herein is a method for performing arterial-spin labeling (“ASL”). The method may include performing a labelling phase and performing a control phase. The labelling phase may include a first plurality of radio frequency (“RF”) pulses, each RF pulse of the first plurality of RF pulses may have a frequency offset and a phase offset. The control phase may include a second plurality of RF pulses, each RF pulse of the second plurality of RF pulses may have the frequency offset and the phase offset and alternating RF pulses of the second plurality of RF pulses may have an additional phase shift.

In at least one example embodiment, the frequency offset may be based on deviations in a B₀ field in a labelling plane. In at least one example embodiment, the frequency offset may be based on a gyromagnetic ratio and the deviations in the B₀ field in the labelling plane.

In at least one example embodiment, the phase offset may be based on the frequency offset and a time between adjacent RF pulses of at least one of the first plurality of RF pulses or the second plurality of RF pulses. In at least one example embodiment, the frequency offset may be based on deviations in a B₀ field in a labelling plane. In at least one example embodiment, the frequency offset may be based on a gyromagnetic ratio and the deviations in the B₀ field in the labelling plane.

In at least one example embodiment, the labelling phase may be a pseudo-continuous ASL labelling phase.

In at least one example embodiment, the control phase may be a pseudo-continuous ASL control phase.

Also described herein is a non-transitory computer readable medium storing computer-executable instruction that, when executed by at least one processor of a system, may cause the system to perform a method for performing arterial-spin labeling (“ASL”). The method may include performing a labelling phase and performing a control phase. The labelling phase may include a first plurality of radio frequency (“RF”) pulses, each RF pulse of the first plurality of RF pulses may have a frequency offset and a phase offset. The control phase may include a second plurality of RF pulses, each RF pulse of the second plurality of RF pulses may have the frequency offset and the phase offset and alternating RF pulses of the second plurality of RF pulses may have an additional phase shift.

In at least one example embodiment, the frequency offset may be based on deviations in a B₀ field in a labelling plane. In at least one example embodiment, the frequency offset may be based on a gyromagnetic ratio and the deviations in the B₀ field in the labelling plane.

In at least one example embodiment, the phase offset may be based on the frequency offset and a time between adjacent RF pulses of at least one of the first plurality of RF pulses or the second plurality of RF pulses. In at least one example embodiment, the frequency offset may be based on deviations in a B₀ field in a labelling plane. In at least one example embodiment, the frequency offset may be based on a gyromagnetic ratio and the deviations in the B₀ field in the labelling plane.

In at least one example embodiment, the labelling phase may be a pseudo-continuous ASL labelling phase.

In at least one example embodiment, the control phase may be a pseudo-continuous ASL control phase.

### BRIEF DESCRIPTION OF THE DRAWINGS

The various features and advantages of the non-limiting embodiments herein may become more apparent upon review of the detailed description in conjunction with the accompanying drawings. The accompanying drawings are merely provided for illustrative purposes and should not be interpreted to limit the scope of the claims. The accompanying drawings are not to be considered as drawn to scale unless explicitly noted. For purposes of clarity, various dimensions of the drawings may have been exaggerated.

FIG. 1A is an illustration of a system for implementing methods according to example embodiments.

FIG. 1B is a block diagram illustrating an example embodiment of the system shown in FIG. 1A.

FIG. 2 is a pseudo-continuous ASL (“pCASL”) labelling module in accordance with at least one example embodiment.

FIG. 3 is a pCASL control module in accordance with at least one example embodiment.

FIG. 4 illustrates perfusion weighted images of an anthropomorphic phantom using pCASL labelling in accordance with at least one example embodiment.

FIG. 5 illustrates a method for performing pCASL in accordance with at least one example embodiment.

### DETAILED DESCRIPTION OF EXAMPLE EMBODIMENTS

Independent of the grammatical term usage, individuals with male, female or other gender identities are included within the term.

Some detailed example embodiments are disclosed herein. However, specific structural and functional details disclosed herein are merely representative for purposes of describing some example embodiments. Example embodiments may, however, be embodied in many alternate forms and should not be construed as limited to only example embodiments set forth herein.

Accordingly, while example embodiments are capable of various modifications and alternative forms, example embodiments thereof are shown by way of example in the drawings and will herein be described in detail. It should be understood, however, that there is no intent to limit an example embodiment to the particular forms disclosed, but to the contrary, example embodiments are to cover all modifications, combinations, equivalents, and alternatives falling within the scope of an example embodiment. Like numbers refer to like elements throughout the description of the figures.

It should be understood that when an element or layer is referred to as being “on,” “connected to,” “coupled to,” or “covering” another element or layer, it may be directly on, connected to, coupled to, or covering the other element or layer or intervening elements or layers may be present. In contrast, when an element is referred to as being “directly on,” “directly connected to,” or “directly coupled to” another element or layer, there are no intervening elements or layers present. Like numbers refer to like elements throughout the specification. As used herein, the term “and/or” includes any and all combinations of one or more of the associated listed items.

It should be understood that, although the terms first, second, third, etc. may be used herein to describe various elements, regions, layers and/or sections, these elements, regions, layers, and/or sections should not be limited by these terms. These terms are only used to distinguish one element, region, layer, or section from another region, layer, or section. Thus, a first element, region, layer, or section discussed below could be termed a second element, region, layer, or section without departing from the teachings of example embodiment.

The terminology used herein is for the purpose of describing various example embodiment only and is not intended to be limiting of example embodiment. As used herein, the singular forms “a,” “an,” and “the” are intended to include the plural forms as well, unless the context clearly indicates otherwise. It will be further understood that the terms “includes,” “including,” “comprises,” and/or “comprising,” when used in this specification, specify the presence of stated features, integers, steps, operations, and/or elements, but do not preclude the presence or addition of one or more other features, integers, steps, operations, elements and/or groups thereof.

When the words “about” and “substantially” are used in this specification in connection with a numerical value, it is intended that the associated numerical value include a tolerance of ±10% around the stated numerical value, unless otherwise explicitly defined. Moreover, when the terms “generally” or “substantially” are used in connection with geometric shapes, it is intended that precision of the geometric shape is not required but that latitude for the shape is within the scope of the disclosure. Furthermore, regardless of whether numerical values or shapes are modified as “about,” “generally,” or “substantially,” it will be understood that these values and shapes should be construed as including a manufacturing or operational tolerance (e.g., ±10%) around the stated numerical values or shapes.

Unless otherwise defined, all terms (including technical and scientific terms) used herein have the same meaning as commonly understood by one of ordinary skill in the art to which example embodiment belong. It will be further understood that terms, including those defined in commonly used dictionaries, should be interpreted as having a meaning that is consistent with their meaning in the context of the relevant art and will not be interpreted in an idealized or overly formal sense unless expressly so defined herein.

Arterial-spin labelling is a non-invasive magnetic resonance (“MR”) technique that may be used for measuring blood perfusion. ASL may include pulsed ASL (“PASL”) where blood surrounding an imaging volume is labeled and continuous ASL (“CASL”) or pseudo-continuous ASL (“pCASL”) where blood up-stream of an imaging volume is labeled using flow-driven adiabatic passage. ASL is a signal to noise ratio (“SNR”) limited technique due to the relatively small amount of blood in the brain that can be used to create contrast. In at least one example embodiment, labelling efficiency is increased for pCASL by using at least one of a phase offset or a frequency offset in the presence of a B₀ field in the labelling plane.

In particular, presence of deviations in a B₀ field in a labelling plane may skew phase calculations of pCASL. Methods of correcting deviations in a B₀ field have been broadly classified into correction methods and shimming methods. Correction methods typically only have three degrees of freedom and thus only provide limited adjustments. Shimming methods attempt to address B₀ field deviations proactively by adjusting a scanner shim in real-time during both a labelling phase and a control phase of pCASL and then adjusting the scanner shim back to a default shim to not impact an imaging readout. Thus, the shim must be switched quickly and in real-time which typically limits available shim channels to the three linear terms of a modern MR scanner and local shim channels. The shimming methods typically have four degrees of freedom and are considered more flexible than correction methods.

Example embodiments of systems and methods described herein provide a pseudo 0th order shim. The 0^{th} order shim on a modern MR scanner is the main magnetic field of the MR scanner, which is a Larmor frequency in MR applications. However, the main magnetic field is fixed in MR scanners and cannot be adjusted after installation of the MR scanner. Thus, both a phase offset and a frequency offset may be introduced to offset deviations of a B₀ field in the labelling plane and provide improved labelling efficiency in pCASL.

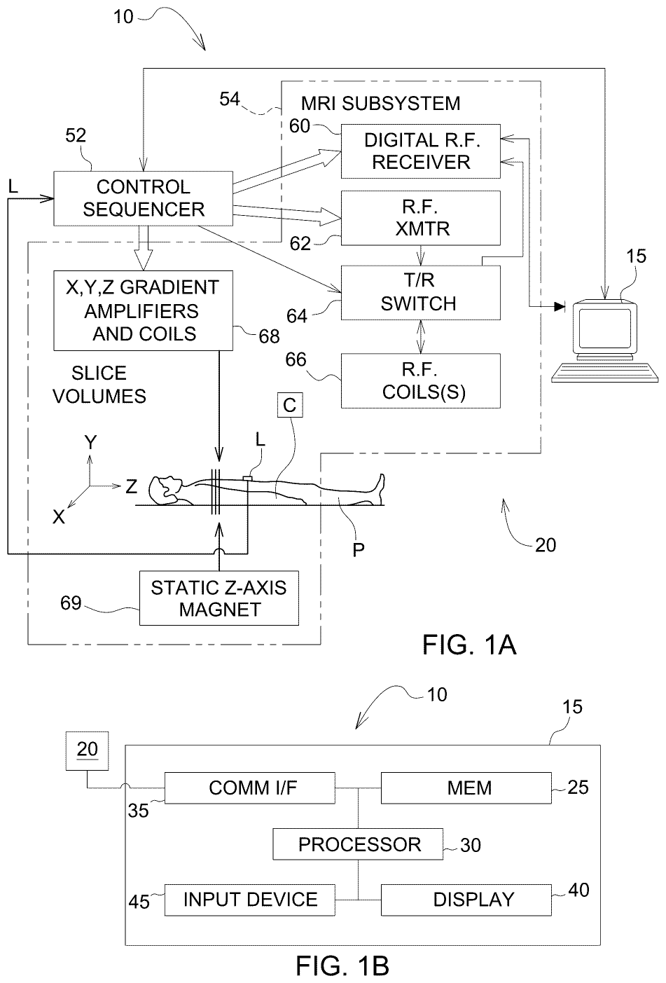

FIG. 1A is an illustration of a system for implementing methods according to example embodiments described herein. FIG. 1B is a block diagram illustrating an example embodiment of the system shown in FIG. 1A. Although one or more example embodiments may be described herein with regard to the systems shown in FIGS. 1A and 1B, example embodiments should not be limited to these examples.

Referring to FIGS. 1A and 1B, a system 10 may include an information processing device 15 and an acquisition device 20. The acquisition device 20 includes a magnetic resonance imaging (“MRI”) real-time control sequencer 52 and an MRI subsystem 54. The MRI subsystem 54 may include XYZ magnetic gradient coils and associated amplifiers 68, a static Z-axis magnet 69, a digital radiofrequency (“RF”) transmitter 62, a digital RF receiver 60, a transmit/receive switch 64, and RF coil(s) 66. The acquisition device 20 may include additional or fewer components in some example embodiments, and may be configured to image a patient.

The MRI subsystem 54 may be controlled in real-time by the MRI real-time control sequencer 52 to generate and measure magnetic field and radio frequency emissions that stimulate nuclear magnetic resonance (“NMR”) phenomena in an object P (e.g., a human or other living body) to be imaged.

The information processing device 15 may implement a method for processing medical data, such as medical image data. As discussed in more detail below, one or more information processing devices such as the information processing device 15 may be configured to implement any or all of the example embodiments described herein.

In FIGS. 1A and 1B, the acquisition device 20 is shown as a separate unit from the information processing device 15. It is, however, possible to integrate the information processing device 15 as part of the acquisition device 20.

The information processing device 15 may include at least one memory 25, processing circuitry including at least one processor 30, at least one communication interface 35 and/or an input device 40. The at least one memory 25 may include various special purpose program code including computer executable instructions which may cause the at least one processor 30 of the information processing device 15 to perform one or more of the methods according to example embodiments described herein. The acquisition device 20 may provide the medical data to the information processing device 15 via the input device 40. In some example embodiments, the information processing device 15 may additionally include a display 45 that may be configured to output information about one or more of an imaging process, the information processing device 15, or the acquisition device 20.

As will be appreciated, depending on the implementation of the system 10, the system 10 may include additional components. However, it is not necessary that all of these generally conventional components be shown in order to disclose the illustrative example embodiment. For example purposes, the system 10 will be discussed with regard to the at least one processor 30. However, it should be understood that the system 10 may include one or more processors or other processing circuitry, such as one or more Application Specific Integrated Circuits (“ASICs). The at least one processor 30 may include, but is not limited to, a central processing unit (“CPU”), an arithmetic logic unit (“ALU”), a graphics processing unit (“GPU”), an application processor (“AP”), a digital signal processor (“DSP”), a microcomputer, a field programmable gate array (“FPGA”), and programmable logic unit, ASIC, a neural network processing unit (“NPU”), an Electronic Control Unit (“ECU”), a quantum computer, and the like. In some example embodiments, the processing circuitry may include a non-transitory computer readable storage medium or device (e.g., memory), for example a solid state drive (“SSD”), storing a program of instructions, and a processor (e.g., CPU) configured to execute the program of instructions to implement the functionality and/or methods performed by some or all of the systems according to any of the example embodiments.

The at least one memory 25 may be a computer readable storage medium that generally includes a random access memory (“RAM”), read only memory (“ROM”), and/or a permanent mass storage device, such as a disk drive. The at least one memory 25 may also store an operating system and any other routines/modules/applications for providing the functionalities of the system 10 to be executed by the at least one processor 30. These software components may also be loaded from a separate computer readable storage medium into the at least one using a drive mechanism (not shown). Such separate computer readable storage medium may include a disc, tape, DVD/CD-ROM drive, memory card, or other like computer readable storage medium (not shown). In some example embodiments, software components may be loaded into the at least one memory 25 via one of the at least one communication interface 35, rather than via a computer readable storage medium.

The at least one processor 30 or other processing circuitry may be configured to carry out instructions of a computer program by performing the arithmetical, logical, and input/output operations of the system. Instructions may be provided to the at least one processor 30 by the at least one memory 25.

The at least one communication interface 35 may be wired and may include components that interface the at least one processor 30 with the other input/output components. As will be understood, the at least one communication interface 35 and programs stored in the at least one memory 25 to set forth the special purpose functionalities of the system 10 will vary depending on the implementation of the system 10.

The at least one communication interface 35 may also include one or more user input devices (e.g., a keyboard, a keypad, a mouse, or the like) and user output devices (e.g., a display, a speaker, or the like).

As disclosed herein, the term “storage medium,” “computer readable storage medium” or “non-transitory computer readable storage medium” may represent one or more devices for storing data, including ROM, RAM, magnetic RAM, core memory, magnetic disk storage mediums, optical storage mediums, flash memory devices and/or other tangible machine-readable mediums for storing information. The term “computer-readable medium” may include, but is not limited to, portable or fixed storage devices, optical storage devices, and various other mediums capable of storing, containing or carrying instruction(s) and/or data.

Furthermore, example embodiments may be implemented by hardware, software, firmware, middleware, microcode, hardware description languages, or any combination thereof. When implemented in software, firmware, middleware or microcode, the program code or code segments to perform the necessary tasks may be stored in a machine or computer readable medium such as a computer readable storage medium. When implemented in software, a processor or processors will perform the necessary tasks. For example, as mentioned above, according to one or more example embodiments, at least one memory may include or store a computer program or computer program code, and the at least one memory and the computer program code may be configured to, with at least one processor, the methods described herein. Additionally, the processor, memory and example algorithms, encoded as computer program code, serve as means for providing or causing performance of operations discussed herein. At least one other example embodiment may include a computer program including program segments or instructions that, when executed by at least one processor of a system, cause the system to perform the functions and methods described herein.

A code segment of a computer program may represent a procedure, function, subprogram, program, routine, subroutine, module, software package, class, or any combination of instructions, data structures or program statements. A code segment may be coupled to another code segment or a hardware circuit by passing and/or receiving information, data, arguments, parameters or memory contents. Information, arguments, parameters, data, etc. may be passed, forwarded, or transmitted via any suitable technique including memory sharing, message passing, token passing, network transmission, etc.

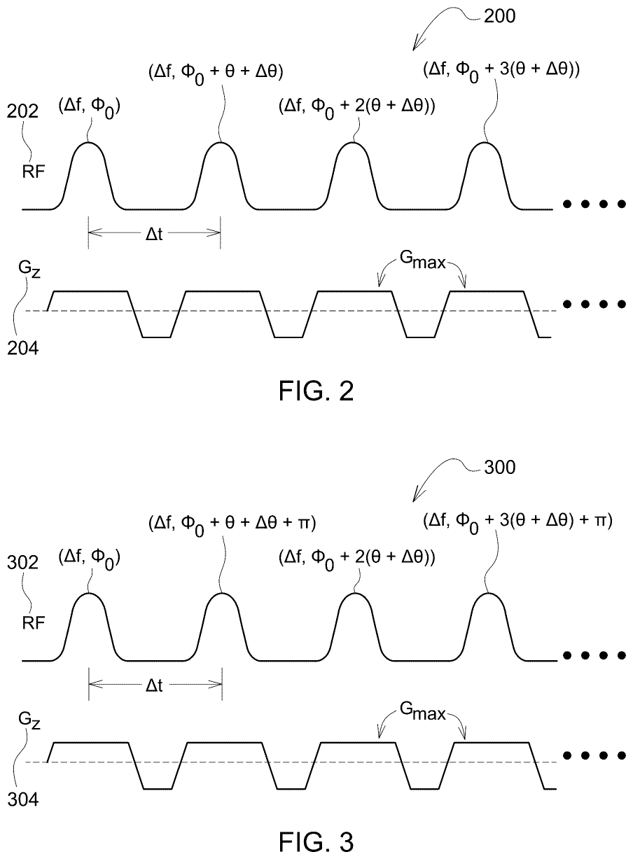

FIGS. 2-5 will be discussed herein with respect to the system 10 of FIGS. 1A and 1B. It should be understood, however, that example embodiments should not be limited to those described herein.

A labelling phase of a pCASL procedure is configured to flip a phase of blood nuclear spin magnetization. The goal of the labelling phase is to invert the phase of blood nuclear spin magnetization. A control phase may follow the labelling phase and may oscillate the phase of blood nuclear spin magnetization around a neutral phase such that the phase of blood nuclear spin magnetization is not inverted.

A labelling phase of a pCASL procedure includes a plurality of RF pulses at a labelling frequency, f_{lab}, with a reference phase, Ø₀, and a phase increment, θ. The labelling frequency, f_{lab}, the reference phase, Ø₀, and the phase increment, θ, may be used to track a phase of blood nuclear spin magnetization during pCASL labelling. In at least one example embodiment, the reference phase, Ø₀, may be arbitrary and the phase increment, θ, may be defined by equation 1:

$$θ = γ {G}_{a v e} Δ z Δ t \qquad [ 1 ]$$

where γ is the gyromagnetic ratio, Δt is a labelling unit defining spacing between two labeling RF pulses, Gₐᵥₑ is the average z-gradient experienced by blood over one labeling unit, Δt, and Δz is the z-distance of the labeling plane from the iso-center of an imaging volume.

During a control phase of pCASL, a phase increment may be applied as described above with respect to the labelling phase with an additional phase shift, π, applied to every other RF pulse to prevent the phase of blood nuclear spin magnetization from being inverted.

In at least one example embodiment, deviations in a B₀ field in the labelling plane may impact the phase calculation such that the phase of blood nuclear spin magnetization is not inverted as desired in a labelling phase or is not maintained at a neutral phase in the control phase. Thus, deviations in the B₀ field in the labelling plane may reduce a labelling efficiency. The systems and methods described herein provide modified pCASL label and control modules to compensate for deviations in the B₀ field in the labelling plane. As described herein, deviations in the B₀ field in the labelling plane may be referred to herein as B₀ off resonance in the labelling plane.

FIG. 2 illustrates a pCASL labelling module 200 in accordance with at least one example embodiment. The pCASL labelling module 200 is the labelling portion of an image acquisition to obtain a “labeled” or “tagged” image, which may be used to generate, for example, a perfusion map.

Referring to FIG. 2, the pCASL labelling module 200 shows a plurality of RF pulses 202 and a z-gradient 204 experienced by blood during the series of RF pulses 202. The x-gradient may oscillate from positive to negative with the application of an RF pulse and may have maximum value of Gₘₐₓ. A labeling unit, Δt, is defined from a peak of a first RF pulse to a peak of a next RF pulse. The pCASL labelling module 200 includes a frequency offset, Δf, and a phase offset, Δθ, for each RF pulse of the plurality of RF pulses 202. In at least one example embodiment, a combination of the frequency offset, Δf, and the phase offset, Δθ, may maximize labelling efficiency during a labelling phase in the presence of a B₀ off resonance in the labelling plane. The frequency offset, Δf, is shown in equation [2] below and the phase offset, Δθ, is shown in equation [3] below:

$$Δ f = \frac{γ}{2 π} Δ {B}_{0} \qquad [ 2 ]$$

$$Δθ = 2 π Δ f Δ t = γ Δ {B}_{0} Δ t \qquad [ 3 ]$$

where γ is the gyromagnetic ratio, Δt is the labelling unit defining spacing between two labeling RF pulses, and ΔB₀ is a B₀ off resonance in the labelling plane.

Thus, a new labelling pulse frequency,

$${f}_{l a b}^{′} ,$$

is the labelling frequency plus the frequency offset shown in equation [4] below:

$${f}_{l a b}^{′} = {f}_{lab} + Δ f = {f}_{lab} + \frac{γ}{2 π} Δ {B}_{0} \qquad [ 4 ]$$

where f_{lab} is a labelling pulse frequency of each RF pulse as applied to each RF pulse during a labelling phase without addition of a frequency offset.

Similarly, a new phase increment, θ′, is defined by a sum of the phase increment and the phase offset as shown in equation [5] below:

$${θ}^{′} = θ + Δ θ = γ ( {G}_{a v e} Δ z + Δ {B}_{0} ) Δ t \qquad [ 5 ]$$

where θ is a phase increment between each RF pulse during a labelling phase without addition of a phase offset.

FIG. 3 is a pCASL control module 300 in accordance with at least one example embodiment. The pCASL control module 300 is the control portion of an image acquisition to obtain a “control” image, which may be used along with the labelled image to generate, for example, a perfusion map. A perfusion map or other resultant image may be generated based on the control image and the labelled image in any known manner.

Referring to FIG. 3, the pCASL control module 300 is similar to the pCASL labelling module 200 and includes a plurality of RF pulses 302 and a z-gradient 304 experienced by blood during the series of RF pulses 302. The pCASL control module 300 further includes a phase shift, π, added to every other RF pulse of the plurality of RF pulses. As described above, the phase shift may prevent the phase of blood nuclear spin magnetization from being inverted during the control phase. The pCASL control module 300 may include the frequency offset, Δf, and the phase offset, Δθ, as described above.

The new labelling pulse frequency,

$${f}_{l a b}^{′} ,$$

and the new phase increment, θ′, may ensure that RF pulses during pCASL are on resonance at the labelling plane. The new labelling pulse frequency,

$${f}_{l a b}^{′} ,$$

snd the new phase increment, θ′, may also more accurately keep track of a blood nuclear spin magnetization during both the labelling and control phases which may help to achieve more optimal labelling efficiency.

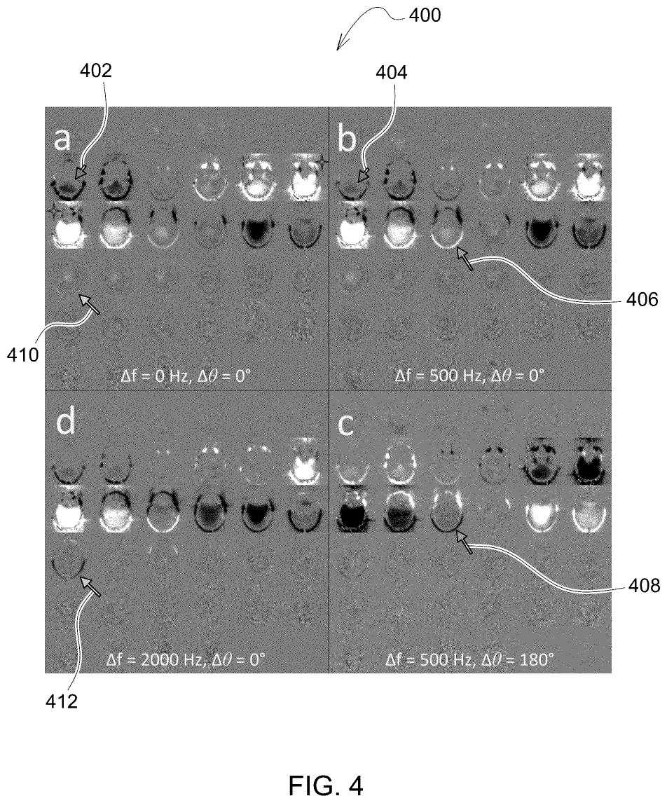

FIG. 4 illustrates perfusion weighted images 400 of an anthropomorphic phantom obtained using pCASL labelling in accordance with at least one example embodiment. The images were obtained by scanning the anthropomorphic phantom using a 2D EPI sequence with pCASL labelling at 7 Tesla. The pCASL labelling and control phase have an RF spacing, Δt, of 1000 μs, Gₘₐₓ of 8 mT/m, Gₐᵥₑ of 1 mT/m, and a z-distance from an iso-center of the imaging volume, Δz, of 20 mm with a distance from a center of imaging slices is 24 mm. The perfusion weighted images 400 obtained with a 2D-EPI readout resulting in a 4 mm isotropic voxel size and 36 slices.

Because the perfusion weighted images 400 are of an anthropomorphic phantom, there is no blood flow. Thus, the labelling plane is positioned within the imaging volume to illustrate an effect of pCASL labelling. The perfusion weighted images 400 are shown in four groups, (a)-(d), with various frequency offsets and phase offsets applied.

Images in block (a) of the perfusion weighted images 400 are shown without either a frequency offset or a phase offset. Images in block (b) of the perfusion weighted images 400 are shown with a frequency offset, Δf, of 500 Hz. Images in block (c) of the perfusion weighted images are shown with a frequency offset, Δf, of 500 Hz and a phase offset, Δθ, of 180°. Images in block (d) of the perfusion weighted images 400 are shown with a frequency offset, Δf, of 2000 Hz.

When comparing the images in block (a) and block (b), it can be seen that the labelling plane is shifted. Thus, arrow 402 shows a slice with more contrast in block (a) than a slice in block (b) illustrated by arrow 404.

When comparing the images in block (b) and block (c), it can be seen that the labelling plan and the control plane have been flipped by the phase offset, Δθ, of 180°. In particular, the slice of arrow 406 of block (b) appears inverted from the slice of arrow 408 of block (c).

When comparing the images in block (a) and block (d), it can be seen that the labelling plane is further shifted than as shown in block (b). Thus, arrow 410 shows a slice with less contrast in block (a) than slice in block (d) shown by arrow 412.

Thus, the perfusion weighted images 400 illustrate that a frequency offset, Δf, is used to accurately position the labeling plane in the presence of B₀ off resonance and a phase offset, Δθ, is used to offset an effect of B₀ off resonance.

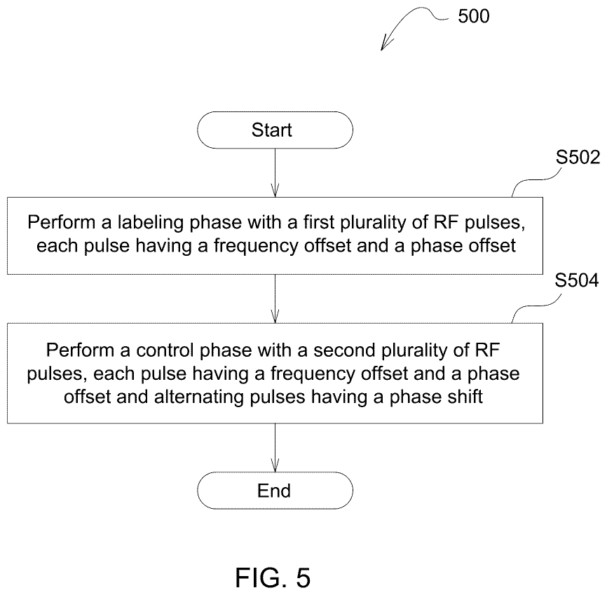

FIG. 5 illustrates a method 500 for performing pCASL in accordance with at least one example embodiment. The method 500 is discussed herein with respect to the system 10 of FIGS. 1A and 1B and the pCASL labelling module 200 and the pCASL control module 300 of FIGS. 2 and 3. It should be understood, however, that example embodiments should not be limited to those described herein.

Referring to FIG. 5, at S502, a pCASL labelling phase is performed by the system 10. The pCASL labelling phase may include the plurality of RF pulses 202 where each pulse has a frequency offset, Δf, and a phase offset, Δθ, as described above. Thus, each RF pulse of the plurality of RF pulses 202 may have a new labelling pulse frequency,

$${f}_{l a b}^{′} ,$$

and a new phrase increment, θ′, as described above.

At S504, a pCASL control phase is performed by the system 10. The pCASL control phase may include the plurality of RF pulses 302 where each pulse has a frequency offset, Δf, and a phase offset, Δθ, as described above. Thus, each RF pulse of the plurality of RF pulses 302 may have a new labelling pulse frequency,

$${f}_{l a b}^{′} ,$$

and a new phase increment, θ′, as described above. Further, every other RF pulse of the plurality of RF pulses 302 may have a phase shift, π.

The frequency offsets, Δf, and the phase offsets, Δθ, applied in the pCASL labelling phase and the pCASL control phase may be based on deviations in a B₀ field in a labelling plane and may be used to increase efficiency of pCASL labelling. Thus, following pCASL, images may be obtained of an imaging volume subject to pCASL. The frequency offsets, Δf, and the phase offsets, Δθ, may offset an effect of a B₀ field in a labelling plane which may result in an improved imaging method.

The above-described systems and methods provide improved pCASL labelling by increasing the efficiency of pCASL labelling. Both frequency offsets, Δf, and the phase offsets, Δθ, may be used to offset deviations in a B₀ field in a labelling plane which may result in an improved pCASL labelling process.

Example embodiments have been disclosed herein, it should be understood that other variations may be possible. Such variations are not to be regarded as a departure from the spirit and scope of the present disclosure, and all such modifications as would be obvious to one skilled in the art are intended to be included within the scope of the following claims.

### NON-LIMITING ILLUSTRATIVE EMBODIMENTS

The following is a list of non-limiting illustrative embodiments disclosed herein:

Illustrative embodiment 1 includes a system for performing arterial-spin labeling (“ASL”), the system comprising: at least one memory configured to store instructions; and at least one processor configured to execute the instructions to cause the system to perform a labelling phase, the labelling phase including a first plurality of radio frequency (“RF”) pulses, each RF pulse of the first plurality of RF pulses having a frequency offset and a phase offset, and perform a control phase, the control phase including a second plurality of RF pulses, each RF pulse of the second plurality of RF pulses having the frequency offset and the phase offset and alternating RF pulses of the second plurality of RF pulses having an additional phase shift.

Illustrative embodiment 2 includes the system of illustrative embodiment 1, wherein the frequency offset is based on deviations in a B₀ field in a labelling plane.

Illustrative embodiment 3 includes the system of illustrative embodiment 2, wherein the frequency offset is based on a gyromagnetic ratio and the deviations in the B₀ field in the labelling plane.

Illustrative embodiment 4 includes the system of any one of the preceding illustrative embodiments, wherein the phase offset is based on the frequency offset and a time between adjacent RF pulses of at least one of the first plurality of RF pulses or the second plurality of RF pulses.

Illustrative embodiment 5 includes the system of illustrative embodiment 4, wherein the frequency offset is based on deviations in a B₀ field in a labelling plane.

Illustrative embodiment 6 includes the system of illustrative embodiment 5, wherein the frequency offset is based on a gyromagnetic ratio and the deviations in the B₀ field in the labelling plane.

Illustrative embodiment 7 includes the system of any one of the preceding illustrative embodiments, wherein the labelling phase is a pseudo-continuous ASL labelling phase.

Illustrative embodiment 8 includes the system of any one of the preceding illustrative embodiments, wherein the control phase is a pseudo-continuous ASL control phase.

Illustrative embodiment 9 includes a method for performing arterial-spin labeling (“ASL”), the method comprising: performing a labelling phase, the labelling phase including a first plurality of radio frequency (“RF”) pulses, each RF pulse of the first plurality of RF pulses having a frequency offset and a phase offset; and performing a control phase, the control phase including a second plurality of RF pulses, each RF pulse of the second plurality of RF pulses having the frequency offset and the phase offset and alternating RF pulses of the second plurality of RF pulses having an additional phase shift.

Illustrative embodiment 10 includes the method of illustrative embodiment 9, wherein the frequency offset is based on deviations in a B₀ field in a labelling plane.

Illustrative embodiment 11 includes the method of illustrative embodiment 10, wherein the frequency offset is based on a gyromagnetic ratio and the deviations in the B₀ field in the labelling plane.

Illustrative embodiment 12 includes the method of any one of illustrative embodiments 9-11, wherein the phase offset is based on the frequency offset and a time between adjacent RF pulses of at least one of the first plurality of RF pulses or the second plurality of RF pulses.

Illustrative embodiment 13 includes the method of illustrative embodiment 12, wherein the frequency offset is based on deviations in a B₀ field in a labelling plane.

Illustrative embodiment 14 includes the method of illustrative embodiment 13, wherein the frequency offset is based on a gyromagnetic ratio and the deviations in the B₀ field in the labelling plane.

Illustrative embodiment 15 includes the method of any one of illustrative embodiments 9-14, wherein the labelling phase is a pseudo-continuous ASL labelling phase.

Illustrative embodiment 16 includes the method of any one of illustrative embodiments 9-15, wherein the control phase is a pseudo-continuous ASL control phase.

Illustrative embodiment 17 includes a non-transitory computer readable medium storing computer-executable instruction that, when executed by at least one processor of a system, cause the system to perform a method for performing arterial-spin labeling (“ASL”), the method comprising: performing a labelling phase, the labelling phase including a first plurality of radio frequency (“RF”) pulses, each RF pulse of the first plurality of RF pulses having a frequency offset and a phase offset; and performing a control phase, the control phase including a second plurality of RF pulses, each RF pulse of the second plurality of RF pulses having the frequency offset and the phase offset and alternating RF pulses of the second plurality of RF pulses having an additional a phase shift.

Illustrative embodiment 18 includes the non-transitory computer readable medium of illustrative embodiment 17, wherein the frequency offset is based on deviations in a B₀ field in a labelling plane.

Illustrative embodiment 19 includes the non-transitory computer readable medium of illustrative embodiment 18, wherein the frequency offset is based on a gyromagnetic ratio and the deviations in the B₀ field in the labelling plane.

Illustrative embodiment 20 includes the non-transitory computer readable medium of any one of illustrative embodiments 17-19, wherein the phase offset is based on the frequency offset and a time between adjacent RF pulses of at least one of the first plurality of RF pulses or the second plurality of RF pulses.

Illustrative embodiment 21 includes the non-transitory computer readable medium of illustrative embodiment 20, wherein the frequency offset is based on deviations in a B₀ field in a labelling plane.

Illustrative embodiment 22 includes the non-transitory computer readable medium of illustrative embodiment 21, wherein the frequency offset is based on a gyromagnetic ratio and the deviations in the B₀ field in the labelling plane.

Illustrative embodiment 23 includes the non-transitory computer readable medium of any one of illustrative embodiments 17-22, wherein the labelling phase is a pseudo-continuous ASL labelling phase.

Illustrative embodiment 24 includes the non-transitory computer readable medium of any one of illustrative embodiments 17-23, wherein the control phase is a pseudo-continuous ASL control phase.

We claim:

1. A system for performing arterial-spin labeling (“ASL”), the system comprising:
at least one memory configured to store instructions; and
at least one processor configured to execute the instructions to cause the system to
perform a labelling phase, the labelling phase including a first plurality of radio frequency (“RF”) pulses, each RF pulse of the first plurality of RF pulses having a frequency offset and a phase offset, and
perform a control phase, the control phase including a second plurality of RF pulses, each RF pulse of the second plurality of RF pulses having the frequency offset and the phase offset and alternating RF pulses of the second plurality of RF pulses having an additional phase shift.

2. The system of claim 1, wherein the frequency offset is based on deviations in a B₀ field in a labelling plane.

3. The system of claim 2, wherein the frequency offset is based on a gyromagnetic ratio and the deviations in the B₀ field in the labelling plane.

4. The system of claim 1, wherein the phase offset is based on the frequency offset and a time between adjacent RF pulses of at least one of the first plurality of RF pulses or the second plurality of RF pulses.

5. The system of claim 4, wherein the frequency offset is based on deviations in a B₀ field in a labelling plane.

6. The system of claim 5, wherein the frequency offset is based on a gyromagnetic ratio and the deviations in the B₀ field in the labelling plane.

7. The system of claim 1, wherein the labelling phase is a pseudo-continuous ASL labelling phase.

8. The system of claim 1, wherein the control phase is a pseudo-continuous ASL control phase.

9. A method for performing arterial-spin labeling (“ASL”), the method comprising:
performing a labelling phase, the labelling phase including a first plurality of radio frequency (“RF”) pulses, each RF pulse of the first plurality of RF pulses having a frequency offset and a phase offset; and
performing a control phase, the control phase including a second plurality of RF pulses, each RF pulse of the second plurality of RF pulses having the frequency offset and the phase offset and alternating RF pulses of the second plurality of RF pulses having an additional phase shift.

10. The method of claim 9, wherein the frequency offset is based on deviations in a B₀ field in a labelling plane.

11. The method of claim 10, wherein the frequency offset is based on a gyromagnetic ratio and the deviations in the B₀ field in the labelling plane.

12. The method of claim 9, wherein the phase offset is based on the frequency offset and a time between adjacent RF pulses of at least one of the first plurality of RF pulses or the second plurality of RF pulses.

13. The method of claim 12, wherein the frequency offset is based on deviations in a B₀ field in a labelling plane.

14. The method of claim 13, wherein the frequency offset is based on a gyromagnetic ratio and the deviations in the B₀ field in the labelling plane.

15. The method of claim 9, wherein the labelling phase is a pseudo-continuous ASL labelling phase.

16. The method of claim 9, wherein the control phase is a pseudo-continuous ASL control phase.

17. A non-transitory computer readable medium storing computer-executable instruction that, when executed by at least one processor of a system, cause the system to perform a method for performing arterial-spin labeling (“ASL”), the method comprising:
performing a labelling phase, the labelling phase including a first plurality of radio frequency (“RF”) pulses, each RF pulse of the first plurality of RF pulses having a frequency offset and a phase offset; and
performing a control phase, the control phase including a second plurality of RF pulses, each RF pulse of the second plurality of RF pulses having the frequency offset and the phase offset and alternating RF pulses of the second plurality of RF pulses having an additional a phase shift.

18. The non-transitory computer readable medium of claim 17, wherein the frequency offset is based on deviations in a B₀ field in a labelling plane.

19. The non-transitory computer readable medium of claim 18, wherein the frequency offset is based on a gyromagnetic ratio and the deviations in the B₀ field in the labelling plane.

20. The non-transitory computer readable medium of claim 17, wherein the phase offset is based on the frequency offset and a time between adjacent RF pulses of at least one of the first plurality of RF pulses or the second plurality of RF pulses.

21. The non-transitory computer readable medium of claim 20, wherein the frequency offset is based on deviations in a B₀ field in a labelling plane.

22. The non-transitory computer readable medium of claim 21, wherein the frequency offset is based on a gyromagnetic ratio and the deviations in the B₀ field in the labelling plane.

23. The non-transitory computer readable medium of claim 17, wherein the labelling phase is a pseudo-continuous ASL labelling phase.

24. The non-transitory computer readable medium of claim 17, wherein the control phase is a pseudo-continuous ASL control phase.
